(19) United States
(12) Patent Application Publication
(10) Pub. No.: US 2021/0318620 A1
(43) Pub. Date: Oct. 14, 2021

(54) SYSTEMS AND METHODS FOR OPTIMIZATION OF PARAMETERS FOR EXPOSING FLEXOGRAPHIC PHOTOPOLYMER PLATES

(71) Applicant: Esko-Graphics Imaging GmbH, Itzehoe (DE)

(72) Inventors: Jörg Wolterink, Oelixdorf (DE); Thomas Hänsel, Elmshorn (DE); Christian Greve, Itzehoe (DE); Frank Grewling, Breitenberg (DE)

(73) Assignee: Esko-Graphics Imaging GmbH, Itzehoe (DE)

(21) Appl. No.: 17/114,642

(22) Filed: Dec. 8, 2020

Related U.S. Application Data
(60) Provisional application No. 63/008,217, filed on Apr. 10, 2020.

(51) Int. Cl. G03F 7/20

(52) U.S. Cl. CPC G03F 7/2051

(57) ABSTRACT

Systems and methods for exposing photopolymer printing plate material located within a target area having first and second dimensions. A light source having LEDs arrayed coextensive with the first dimension moves relative to the second dimension, and emits different light intensities over the target area in at least one of the first dimension or the second dimension. The systems and methods may be used to determine exposure parameters for curing a selected plate by causing different sample units to receive different amounts of total energy exposure, exposure energy per exposure step, or a combination thereof, and visually evaluating each sample unit against a reference plate of the same type and thickness. The sample unit embodying a minimum acceptable total exposure energy and a maximum acceptable exposure energy per exposure step is then identified.

### CROSS-REFERENCE TO RELATED APPLICATIONS

This application claims priority from U.S. Provisional Application Ser. No. 63/008,217, filed Apr. 10, 2020, titled SYSTEMS AND METHODS FOR OPTIMIZATION OF PARAMETERS FOR EXPOSING FLEXOGRAPHIC PHOTOPOLYMER PLATES, the contents of which are incorporated herein by reference.

### BACKGROUND OF THE INVENTION

Exposing flexographic photopolymer printing plates using ultraviolet (UV) light-emitting-diode (LED) light sources to create flat-top printing structures is disclosed generally in one or more applications and granted patents filed by or issued to the owner of the present invention, including as described in, for example, Published U.S. Patent Application Nos. US 2008/0280227A1 (granted as U.S. Pat. No. 8,389,203, and others), US 2009/0294696A1 (granted as U.S. Pat. No. 8,227,769), and US 2011/0104615A1 (granted as U.S. Pat. No. 8,820,234). One challenge in using such systems and methods is that finding the right exposure parameters may be relatively complicated.

In prior art systems utilizing “bank exposure” methods in which a row of stationary fluorescent tubes are arranged in a plane above the polymer plate, only exposure time had to be adjusted based upon known plate sensitivity and available UV output from the tubes.

With the advent of more modern UV LED exposure units, such as but not limited to, the Esko Digital Inline UV™ or the Esko XPS Crystal™ exposure units, additional parameters, such as the light intensity, may benefit from optimization, as LEDs can be continuously adjusted within the full range of 0 and 100% light output.

Many modern LED exposure units impart relative motion between the polymer plate and the UV light source, and therefore the speed of this relative movement is another variable available for optimization. Another parameter, referred to as “pixel time,” may be used instead of speed. “Pixel time” is defined as the amount of time that a single spot on the plate surface is exposed to UV light for a given speed and dimension of the moving UV light source, as is explained further herein.

The number of exposure cycles applied during complete exposure of a polymer plate is yet another parameter available for optimization.

Thus, while prior art fluorescent tube bank exposure systems had only one degree of freedom—exposure time—there are at least three parameters (intensity, pixel time, number of cycles) in exemplary UV LED exposure systems that permit an extremely wide range of parameter combinations.

One advantage of having multiple parameters is the possibility of optimizing certain aspects of the plate properties for printing, including but not limited to:
Smooth fade out of highlight dots
Low or no dot bridging in mid-tones
Linear tonal response
Low fluting effects for corrugated printing
No line broadening
Precise micro texture for high solid ink density

A disadvantage is that one set of the foregoing parameters may be optimal for only one type of photopolymer plate. A plate comprising another photopolymer, or another thickness of the same photopolymer, may have a different set of optimized parameters.

The use of UV LED systems for exposing highly sensitive photopolymer plates originally developed for bank exposure systems has also been noted to cause an undesirable line broadening effect. Line broadening may be particularly problematic with respect to highly sensitive photo polymer plates such as MacDermid® ITP™ or DuPont® Cyrel® EASY or Flint Group® nyoflex® FTH or FTS plates. Those plates were developed by plate manufacturers to allow flat top exposures using fluorescent tube bank exposure units, and they differ from conventional plates by having a relatively more photo initiators. The relatively higher number of starter molecules for the chain reaction of photo polymerisation reduces the effect of oxygen inhibition on polymerization, which helps to facilitate the creation of flat top structures on the printing surface of the plates. The disadvantage of these plates is that when exposed with high-intensity UV LEDs, the support shoulders may become much broader then when exposed with a fluorescent tube bank exposure unit.

This strong growth of the support shoulders may cause the printing details they support to print much broader than desired. Because this effect is typically most visible with thin straight lines, it has been referred to as the “line broadening effect.” FIG. 1A depicts the profile of a normal line, while FIG. 1B depicts the corresponding profile of a “broadened” line. FIG. 2 shows the effect on a printed page. The horizontal lines are wider on the right side of the printed graphics, where there are no surrounding letters to reduce the contact pressure on the line. A line with a profile of FIG. 1A prints with the same line width regardless of whether it is surrounded by other printing details or stands alone. Parameter optimization can reduce or eliminate this line broadening effect.

Completely curing each flexographic polymer plate requires a certain amount of energy per surface unit. For a standard DuPont® DPR 045 plate, for example, this parameter is about 13 J/cm². Determining the total exposure energy for a polymer plate can be readily determined using bank exposure processes. The UV intensity or irradiance in mW/cm² emitted from the fluorescent tubes multiplied by the exposure time in seconds yields a calculated energy-per-unit-area. This basic calculation is the same for UV plate curing by multiple exposure cycles, as discussed in more detail in U.S. Pat. No. 8,227,769, titled “CURING OF PHOTO-CURABLE PRINTING PLATES WITH FLAT TOPS OR ROUND TOPS,” incorporated herein by reference. Although discussed therein in the context of flat top dots, it should be understood that similar calculations apply to round top dots, and the invention as disclosed herein is not limited to any particular type of dot.

In an LED exposure system with multiple exposure cycles, the exposure is divided into individual exposure steps and the total energy-per-surface-area is the sum of the energies of all of the individual exposure steps. While the number of exposure steps may be varied, the total energy-per-surface-area of all exposure steps remains constant.

By changing the number of exposure steps and irradiance while maintaining the total energy-per-surface-area, many pairs of values are possible. In the past, the search for an acceptable pair of values concentrated on finding the first pair that would avoid cupping and dot bridging effects while also providing an acceptable smoothness for the tonal transition in the print.

The parameters as discussed above for optimizing exposure may be represented in a three-dimensional matrix of settings that provide unacceptable or acceptable printing results for each of the aspects listed above. It may be difficult to evaluate each set of parameters in the matrix because printed results are important to obtaining a final assessment, and it may take several trials to identify the settings that provide acceptable printing results. Plate making and printing is often very time consuming, and therefore it may take a substantial amount of time (e.g. several weeks) before all parameters for one plate have been correctly identified.

Accordingly, there is a need in the field for methods of finding combinations of parameters that maximize printing performance using a minimal number of trials for evaluating performance.

### SUMMARY OF THE INVENTION

One aspect of the invention comprises a system for exposing a front, printing side of photopolymer printing plate material located within a target area defined by a first dimension and second dimension, the system comprising a light source comprising a plurality of light emitting diodes (LEDs) arranged in an array coextensive with the first dimension, means for causing relative movement between the light source and the target area along the second dimension, and a control system. The control system is configurable to cause the light source to emit different light intensities over corresponding portions of the target area in at least one of the first dimension or the second dimension such that the corresponding portions of the target area receive correspondingly different amounts of radiation. The array comprising the plurality of LEDs may have at least two sections, each section comprising a subset of the plurality of LEDs, wherein the control system is configurable to cause the at least two sections of the light source to emit different light intensities simultaneously. The control system may also be configurable to cause the light source to emit different a first light intensity over a first portion of the second dimension and a second light intensity over a second portion of the second dimension. The control system may further be configured to cause multiple exposure steps and to cause no light to be emitted by at least a portion of the light source over at least a portion of at least one exposure step.

In some embodiments, the photopolymer printing plate material located within the target area may include a plurality of patches of plate material, including at least two patches having different plate characteristics, such as different types of photopolymer material or different thicknesses of a same photopolymer material. In one embodiment, the light source is stationary and the target area comprises a cylinder having a width in the first dimension and a circumferential area in the second dimension, and the cylinder is configured to rotate beneath the light source to cause the relative movement. In another embodiment, the target area is stationary, and the light source comprises a linear source, having a linear dimension coextensive with the first dimension and a width less than the second dimension, mounted to a carriage configured to move in the second dimension to cause the relative movement. In still other embodiments, the plurality of LEDs include a plurality of stationary front sources arrayed across an entirety of the first dimension and the second dimension of a stationary target area, and the means for causing relative movement between the light source and the target area comprises a configuration of the controller adapted to activate and deactivate different portions of the array such that activated portions move across the array over time.

Another aspect of the invention comprises a light source comprising a plurality of light emitting diodes (LEDs) arranged in an array coextensive with a first dimension and a controller configured to control light intensity of independently controllable subsets of the plurality of LEDs. The light source is configurable to emit different light intensities simultaneously from at least a first section comprising a first subset of the plurality of LEDs positioned in a first portion of the first dimension, and at least a second section comprising a second subset of the plurality of LEDs positioned in a second portion of the first dimension. The light source may be configurable to emit different light intensities simultaneously from a variable number of subsets, to vary a number of LEDs in each subset, and vary the positions of the respective subsets. Methods of using the subject light source to expose printing plate material may include exposing a front (printing) side or back (non-printing) side of the printing plate material.

Still another aspect of the invention is a method for exposing a front, printing side of photopolymer printing plate material located within a target area defined by a first dimension and second dimension. The method comprises causing relative movement between the light source and the target area along the second dimension, and causing the light source to emit different light intensities over corresponding portions of the target area in at least one of the first dimension or the second dimension such that the corresponding portions of the target area receive correspondingly different amounts of radiation. The array may comprise the plurality of LEDs having at least two sections, each section comprising a subset of the plurality of LEDs, wherein the method comprises causing the at least two sections of the light source to emit different light intensities simultaneously. The light source may also or instead emit different a first light intensity over a first portion of the relative movement and a second light intensity over a second portion of the relative movement. In a method including making multiple passes of relative movement along the second dimension, the light source may emit no light over at least a portion of at least one pass.

Yet another aspect of the invention comprises a method for determining exposure parameters for curing a selected photopolymer plate having a predetermined photopolymer type and a predetermined plate thickness over multiple exposure steps. The method comprising the steps of disposing a sample of photopolymer material in a target area, the sample having the predetermined photopolymer type and the predetermined plate thickness, the target area having a first dimension and second dimension; providing a first exposure unit comprising a light source comprising a plurality of LEDs arranged in an array coextensive with the first dimension; and causing relative movement between the light source and the target area along the second dimension. Different units of the sample are caused to receive different amounts of total energy exposure, different amounts of exposure energy per exposure step, or a combination thereof. Each sample unit is visually evaluated against a reference plate having the predetermined photopolymer type and the predetermined plate thickness to identify a sample unit embodying a minimum acceptable total exposure energy and a maximum acceptable exposure energy per exposure step.

The reference plate may be created by selecting an unexposed reference plate having the predetermined photopolymer type and the predetermined plate thickness; producing an exposed reference plate from the unexposed reference plate using a second exposure unit different from the first exposure unit; and certifying the exposed reference plate as having acceptable quality with respect to a plurality of evaluation parameters. The method may include providing one or more sample candidates having the predetermined photopolymer type and the predetermined plate thickness, exposing each of the sample candidates or one or more portions thereof to different levels of total back-side energy, and identifying the total back-side exposure energy corresponding to a desired floor depth. The plurality of criteria for visually assessing the sample against the reference plate for determining the minimum total exposure energy may include criteria for determining a minimum stable dot size, such as, for example: first stable dot in a highlight screen field; dot size of the first stable dot in the highlight screen field; first stable Dotfail test, middle row; first stable Dotfail test, bottom row; first stable isolated dot; and any combination of the foregoing. The plurality of criteria for visually assessing the sample against the reference plate for determining the maximum acceptable exposure energy per exposure step may include line broadening of horizontal lines; line broadening of vertical lines; dot cupping in a predetermined percentage (e.g. 50%) screen, or any combination of the foregoing.

One embodiment of the method includes exposing a first sample unit using exposure parameters including a value below the maximum acceptable exposure energy per exposure step and a first number of exposure steps embodying a minimum number of steps at the maximum acceptable exposure energy needed to reach the minimum acceptable total exposure energy; exposing one or more additional sample units using more than the minimum number of steps; and forming one or more printed sheets using each of the first sample unit and the one or more additional sample units. The printed sheets are visually analysed to identify exposure parameters corresponding to a desired printed result as an optimum set of exposure parameters for the selected photopolymer plate.

In one embodiment, the step of causing different sample units to receive different amounts of total energy exposure overall, per exposure step, or a combination thereof, may comprise exposing an entirety of a first test plate area to a first amount of total energy exposure and a first amount of exposure energy per exposure step, and exposing an entirety of a second test plate area to at least one of: a second amount of total energy exposure different than the first amount of total energy exposure, or a second amount of exposure energy per exposure step different than the first amount of exposure energy per exposure step.

In another embodiment, the step of causing different sample units to receive different amounts of total energy overall, per exposure step, or a combination thereof, may comprise exposing a first sub-area of a first test plate to a first amount of total energy exposure and a first amount of exposure energy per exposure step, and exposing a second sub-area of the first test plate area to at least one of: a second amount of total energy exposure different than the first amount of total energy exposure, or a second amount of exposure energy per exposure step different than the first amount of exposure energy per exposure step. The light source may emit different light intensities over corresponding portions of the first test plate in at least one of the first dimension or the second dimension. A portion of the light source may emit no light at least over a portion of at least one exposure step. The sample of photopolymer material in the target area may comprise a plurality of patches of plate material, including at least one patch with a first predetermined photopolymer type and a first predetermined plate thickness, and at least one other patch having a photopolymer type or plate thickness different from the first plate.

### BRIEF DESCRIPTION OF THE DRAWINGS

FIG. 1A depicts a prior art printing plate line feature with a desired shoulder cross-sectional geometry.

FIG. 1B depicts a prior art printing plate line feature with a relatively broader shoulder cross-sectional geometry as compared to that of FIG. 1A.

FIG. 2 depicts an effect on printing caused by printing plate line features having an undesirably broad cross-sectional geometry.

FIG. 3 depicts an exemplary printing plate divided into three areas A, B, and C along a dimension of the plate coextensive with a direction or relative motion during an exposure step, each of which is designated to receive a different exposure intensity in accordance with an embodiment of the invention.

FIG. 4 highlights intermediate areas of the plate of FIG. 3 in which the receipt of different exposure intensities in adjacent areas leaves a gradient in total exposure.

FIG. 5 is a table corresponding to a plurality of individually controllable LED boards in a light source, and exemplary intensity settings for different boards in different passes for carrying out an exemplary method as described herein.

FIG. 6 schematically depicts an exemplary linear light source having three separately controllable areas in a flatbed arrangement relative to a printing plate.

FIG. 7 depicts areas of an exemplary printing plate designated to receive different exposure intensities in each of a plurality of portions 1A-3C.

FIG. 8 highlights intermediate areas of the plate of FIG. 7 in which the receipt of different exposure intensities in adjacent areas leaves gradients in total exposure.

FIG. 9 depicts a target area for receiving radiation, in which a plurality of patches of plate material are disposed.

FIGS. 10A, 10B, 10C depict exemplary portions of magnified Dotfail screens such as may be incorporated in a Dotfail test array, as depicted in FIG. 11.

FIG. 11 depicts an exemplary Dotfail test array comprising screens comprising dots of increasing pixel sizes from left to right and increasing spacing from top to bottom.

### DETAILED DESCRIPTION OF THE INVENTION

Aspects of the invention include methods for determining exposure parameters for UV exposure of a flexographic photopolymer plate using multiple exposure steps with UV LED sources. While exemplary methods as discussed herein may refer to a UV exposure system such as the Esko XPS UV exposure unit, the methods are not limited to any particular arrangement, and are particularly applicable to any systems that expose the front and/or back of the plate using LED sources that extend over one plate dimension during relative motion between the source and the plate in the other plate dimension.

Parameters that may be optimized by this method include:
UV light irradiance/exposure energy per exposure step
Number of consecutive exposure steps
Speed of the exposure heads during UV exposure/time that one point or pixel on the plate is exposed to UV light during a single exposure step

A benefit of some embodiments of the systems and methods as described herein is a reduction in effort for determining UV plate exposure parameters for a photopolymer printing plate exposed on a UV LED exposure device with linear light sources and relative movement between light source and plate. Accomplishing this goal can be optimized by identifying UV exposure parameters for a given plate with a fewest number of trials and by increasing the number of samples that can be created with a single exposure procedure on a single photopolymer plate. A UV exposure apparatus comprising a light source divided into 2 or more sections, each section having a different light intensity, which permits exposure of 2 or more polymer plate samples simultaneously, may be useful in implementing the method.

Relative movement between the plate and the UV head can be defined by the velocity of the movement; however, for calculation of the exposure energy per exposure step, the velocity (v) requires additional calculations that consider the area (A) of the UV head in the direction of the movement. To make calculations easier, “pixel time” may be used as the parameter to optimize. Pixel time (pT) is defined as the amount of time the UV head illuminates one point on the plate surface, and thus it takes into account speed of movement and extension of the UV head in direction of the movement. An exemplary unit for pixel time is seconds, which can be directly multiplied by UV intensity to calculate exposure energy.

Pixel time is calculated by:

pT=A/v

This way of calculating of polymer plate exposure is adapted to the calculations of the classic bank exposure, in which exposure time multiplied by UV output determined the amount of energy applied to the plate.

Relative movement between the light source and a target area for receiving plate material can be provided by any mechanisms or means known in the art. While systems comprising a plate mounted on a cylinder configured to rotate past a stationary light source, and systems comprising a plate disposed on a flat bed with the light source mounted on a carriage configured to traverse the bed from end to end are most common, any type of mechanism for creating relative movement may be provided. As the cost of LED sources decreases over time, flatbed systems in which a plurality of LED sources are arrayed in rows and columns that cover the full length and width of plate may also be provided, in which case the “relative movement” comprises sections of the array turned on and off such that locations of active radiation move relative to the plate over time. Such relative movement that comprises the activated areas of the light source moving from one location over the plate to another provides pixel time in bursts, separated by resting periods, that mimics the on/off time inherent in physical relative movement. Notably, in a full array system, the sequencing of activated and inactivated regions of the light source can be ordered in a non-linear fashion, and may in some instances be provided more quickly than systems that require physical movement of light source or plate. Systems for providing relative movement, including for providing a full array exposure, are described generally in U.S. application Ser. No. 15/926,616, published as US20180210345A1, titled PROCESS AND APPARATUS FOR CONTROLLED EXPOSURE OF FLEXOGRAPHIC PRINTING PLATES AND ADJUSTING THE FLOOR THEREOF, incorporated herein by reference. To the extent the systems and methods as described in the aforementioned patent relate to systems with coordinated front and back exposure and/or with one or more back-exposure-only steps, the systems and methods of the present invention may also benefit from, but are not limited to, systems that provide coordinated front and back exposure steps, or one or more back-exposure-only steps.

An exemplary evaluation method may be divided into two phases -- a first phase in which plates are cured and processed for assessment, and a second phase in which plates are cured, processed, and printed for assessment. An exemplary method may include the following steps for parameter evaluation:

1. A plate of a predetermined polymer type and predetermined plate thickness is selected for evaluation.

2. A reference plate of the selected plate type is produced on a first exposure device (e.g. a fluorescent tube bank exposure unit) with best available quality using best practices.

3. An acceptable backside exposure energy for the selected plate is derived by creating several samples while stepwise increasing back side UV intensity, and evaluating the plates created thereby to determine an acceptable UV intensity value or UV intensity range that produces a desired floor depth.

4. In a first front-side exposure approximation step, a limited number (e.g. 6-8) plate samples with a fixed number of exposure steps and fixed pixel time are cured while the UV intensity, and consequently the total exposure energy, is increased from one sample to the next. All samples are exposed to the same amount of back exposure energy, such as the value, or a value from the range of values, determined in step 3.

5. After the plate of step 4 has been completely processed, the samples are assessed by visual comparison to the reference plate using a plurality of criteria for evaluating smallest stable dot size, including, for example:

a. First stable dots in highlight screen field

b. Dot size (e.g. tip diameter) of the first stable dots in the highlight screen field

c. First stable Dotfail test, middle row

d. First stable Dotfail test, bottom row

e. First stable isolated dot in Dotfail test

The “first stable dots in highlight screen field” references the screen percentage that delivers the first stable dots in the highlights, such as by using a particular reference tonal curve for linearizing the tonal values of different screen percentages (e.g. Esko's H34 curve). This aspect of the invention is not limited to any particular highlight dot or tonal curve, however.

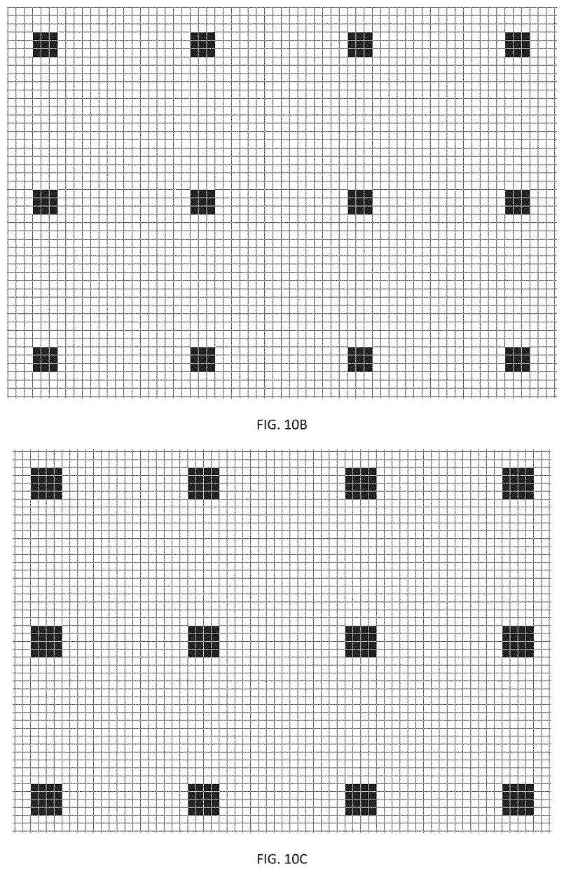

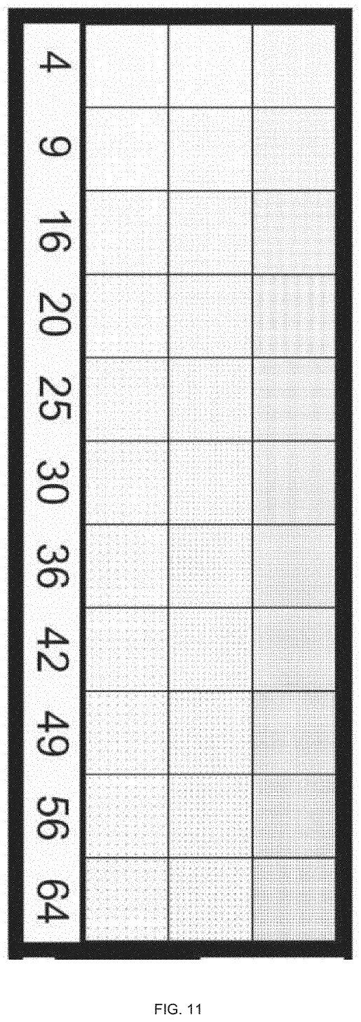

The “Dotfail test” referenced above refers to a test pattern of squared dots created from 2×2, 3×3 , 4×4 , 5×5, etc. pixel clusters located different distances to one another, such as are shown in FIGS. 10A-10C, and collectively arranged in a plurality of at least three rows, as shown in FIG. 11. The top row (parallel to and furthest from the numbers) has the closest spacing of dots (which tend to be most stable), whereas the middle row has a greater spacing relative to the top row, and bottom row has an even greater spacing than the middle row. The sizes of the dots (number of pixels) increases from right to left (e.g. from a 4 pixel dot (2×2) in the leftmost column to a 64 pixel dot (8×8) in the rightmost column). The first “stable” dot refers to the first dot size, moving from left to right (smaller to larger size), wherein the dots are stable enough to print. The invention is not limited to any particular types of tests or criteria within such test for determining stable dot size, and therefore the foregoing is provided for illustration of one suitable test and criteria measuable by that test.

The “isolated” dot refers to a 3×3 dot spaced from other dots by an isolation distance that is far enough away (e.g. typically 3-5 mm) from any surrounding dots of any size that the presence or absence of surrounding dots beyond that isolation distance have no influence on the stability of the dot under the predetermined printing conditions.

The lowest total exposure energy that produces a sample meeting all criteria matching the reference plate is selected for further evaluation. This energy is regarded as the minimum total exposure energy required for proper curing of the selected polymer plate.

6. In a second assessment step, the lowest energy per exposure cycle is identified that does not show more line broadening effects and cupping than the reference plate. Assessment relative to the reference plate may include a plurality of criteria, such as for example:

a. Line broadening of horizontal lines

b. Line broadening of vertical lines

c. Dot cupping in selected percentage (e.g. 50%) screen

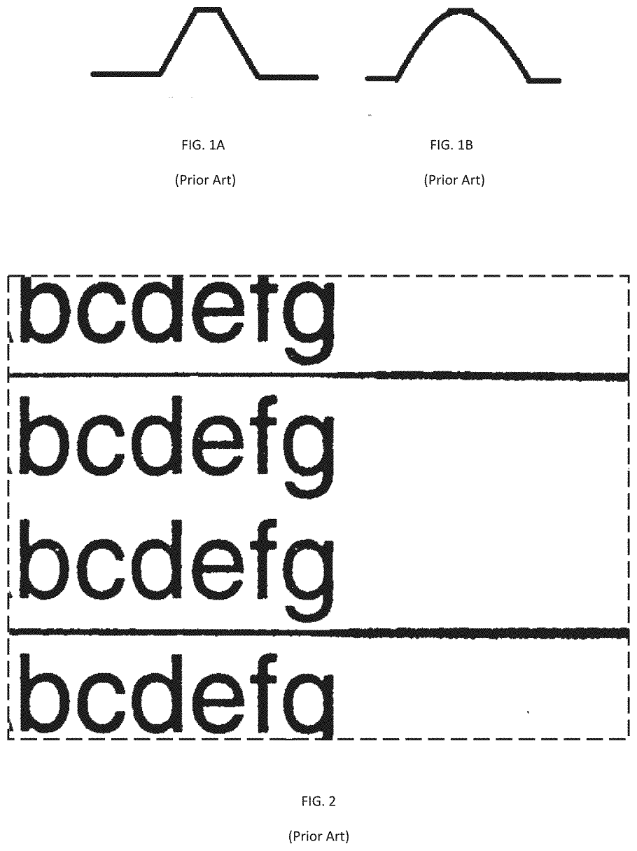

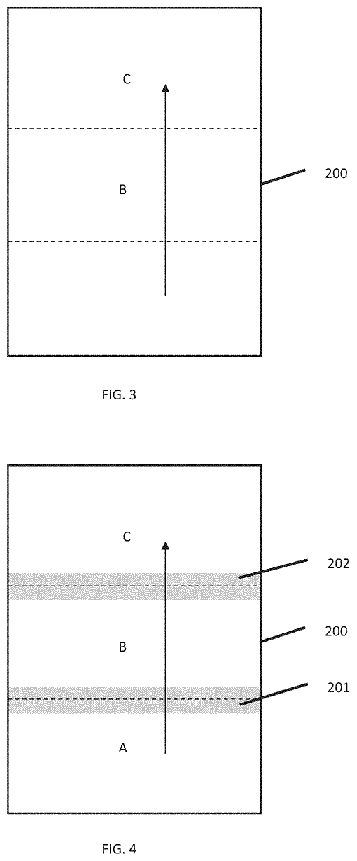

Line broadening is illustrated in FIGS. 1B and 2, and discussed in more detail below. The principle of dot cupping is well understood by those in the prior art, such as is depicted, for example, in FIGS. 4B and 4C of U.S. Pat. No. 8,820,234 and in FIGS. 3 and 4 of U.S. Pat. No. 10,175,580, and discussed in the related specifications, all of which are incorporated herein for those teachings. While a 50% screen is provided as one example, without being limited to any particular percentage, any size from about 20% to a percentage in which the dots are not touching each other is generally accepted to be useful for assessing cupping effects.

This identified energy per exposure cycle is regarded as the threshold energy beyond above which line broadening effects occur.

7. Exposure parameters for the print test plate are calculated from an energy value slightly below the threshold energy corresponding to the onset of line broadening effects as observed in Step 6 a and b, above, and at the minimum exposure energy as determined in Step 5, above. Thus, for example, performing Step 6 may include generating a series of samples over a range of incrementally increasing energy values. If line broadening effects are observed in, e.g., the third sample in that series, then the second sample will be selected as the threshold energy to be used as the exposure parameter for the print test plate. As it is desirable to have the shortest possible overall process time, this calculation will take the shortest technical possible pixel time as a basis, with an increase in pixel time provided only if the maximum required energy is higher than the energy that can be achieved with the maximum UV intensity. While the UV intensity is chosen according to the threshold energy for line broadening, the number of exposure cycles is selected appropriate to the minimum total energy.

8. The plates for the print test are exposed with parameters calculated in step 7, including a first plate test sample having the lowest possible number of exposure steps that meet the requirements and one or more additional plate test samples having a higher number of exposure steps, with energy per exposure step held constant.

9. The prints are analysed, and the set of parameters producing the best print results is selected as the recommended set of exposure parameters for the evaluated plate.

### Solving the Line Broadening Problem

The inventors have discovered that there is a threshold energy-per-exposure step beyond which dot bridging is avoided but line broadening will still occur. Line broadening effects can be minimized if this threshold energy is not exceeded. This threshold is different for each polymer type and plate thickness. Step 6 of the above listed method provides instructions for evaluating minimization of line broadening in addition to optimizing other artefacts on the plates.

### Methods for Increasing the Number of Samples Per Exposure

The evaluation of the exposure parameters for one plate type as described herein above typically benefits from the use of multiple plate samples. Each plate sample requires a time-consuming number of process steps from imaging to printing. While the method as described above minimizes the number of plate samples needed to evaluate the parameters, the inventors have recognized that being able to evaluate multiple sets of parameters on a single plate would decrease cost, time, and manpower, as well as minimize the time that processing equipment is occupied for such evaluations. Not only does having a multitude of samples on one plate greatly reduces the evaluation effort, time and costs, it also enables customers to produce evaluation samples and send them for assessment to the evaluation teams of the plate or exposure system producers. This reduces workload from the application teams and minimizes the number of plates to be shipped (and consumed) for evaluation.

Thus, one aspect of the invention comprises a light source comprising a plurality of UV LEDs arranged in an array coextensive with the first dimension, means for causing relative movement between the light source and the target area in a path along the second dimension, and a control system configurable to cause the light source to emit different light intensities over corresponding portions of the target area in at least one of the first dimension or the second dimension.

Notably, a difference between prior art control systems and the control systems as described herein below, is that the control system is configurable to cause the light source to emit different light intensities over corresponding portions of the target area in at least one of the first dimension or the second dimension in a single exposure step or pass. By contrast, one use of independently controllable portions of LED light sources as described in U.S. Pat. No. 8,227,769, was for creating printing features with flat tops or round tops, based upon applying different exposure intensities in different exposure steps, but in which the total energy received by the plate was homogenous across the entire plate, not different in one portion relative to another.

Similarly, to the extent that published application US20180210345A1 discloses independently controllable portions of LED light sources, this control was disclosed for providing a homogenous output (e.g. the same light intensity output) across the array of LED sources, such as to compensate for slight variations in the actual output from the LEDs or groups thereof, due to variations in the LEDs, soldering to the circuit board, cooling, decay or wear over time, and the like. By contrast, the control system as described herein is configurable to cause the light source to emit different light intensities over corresponding portions of the target area in at least one of the first dimension or the second dimension such that the corresponding portions of the target area receive correspondingly different amounts of radiation.

While methods for controlling light intensity are not limited to any particular method, in some embodiments, the intensity may be controlled by pulse width modulation, in which the nominal current through the LEDs remains the same for all intensity settings, but the output is dimmed by pulsing the LEDs on and off, in which intensity is varied by adjusting the percentage of the time the LED is on relative to the time it is off. A relatively low frequency (e.g. around 2 kHz) has been found to be effective for plate exposure, but the invention is not limited to any particular pulse width frequency, nor to the use of pulse width frequency as the method of adjusting intensity.

### Increasing the Number of Samples in Direction of Relative Movement

One system improvement that reduces the number of plates needed for such evaluations includes a modification to the UV system that allows creation of more samples per plate. In particular, the number of samples per plate can be increased by changing the UV intensity stepwise while the UV Light source travels along the front side of plate in direction of relative motion between light source and polymer plate. Although stepwise changing the back-side exposure intensity in the direction of travel has been used in the field for running a floor check for a new batch of plates, the techniques as described herein include using stepwise changes for front side exposures.

FIG. 3 shows an example of a plate 200, divided into 3 sections A, B and C by the dashed lines. The dashed lines show the boundaries where intensity is altered while the UV Head travels along plate 200 in direction of the arrow.

Changing the intensity stepwise in direction of the relative motion creates a gap of inhomogeneous irradiance, such as the grey areas 201 and 202 of plate 200 in FIG. 4. These areas are not used for evaluating test exposure.

### Increasing Samples Along the Direction of the Linear Light Source

To have even more samples on one plate, a linear light source may be divided into different sections along its linear dimension, in which each section emits different intensity levels. Usually, linear UV LED light sources in an UV exposure system for photopolymer plates have a plurality of LED sections that can be controlled in intensity independently from each other. This allows adjustment to provide a homogenous light output over the length of the light source and makes those sources easily scalable in length. FIG. 5 is an example of an exposure scheme for an Esko UV light source divided into 15 sections. Each section corresponds to an individual LED board, each board having its own controller. Only small modifications to the control system may be necessary to establish sections of different UV light intensity along the length of the linear light source.

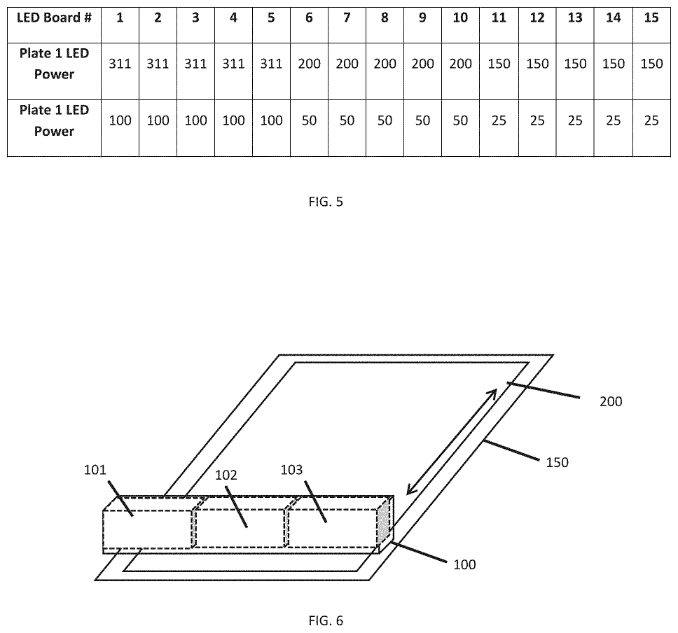

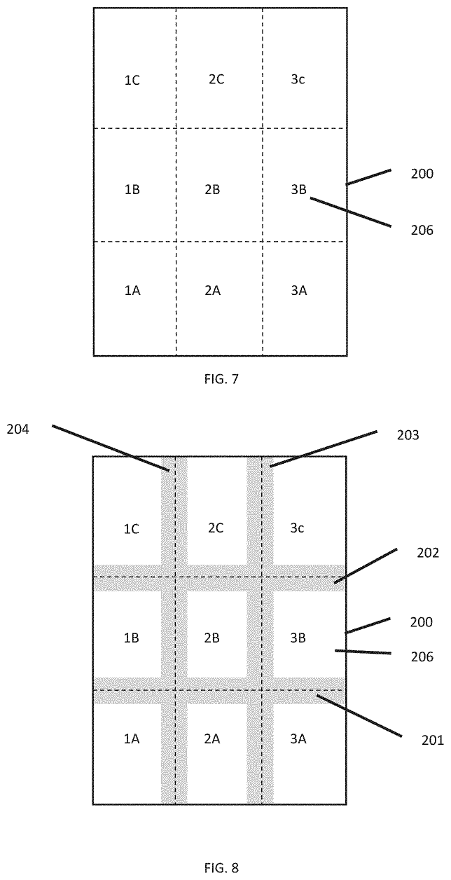

FIG. 6 shows a UV light source 100 divided into 3 sections (101-103) each section having a different UV intensity. Under the UV head is a support surface 150 that receives the photopolymer plate 200. In one exemplary embodiment, such as that shown in FIG. 5, each section comprises five consecutive LED boards, each set of five consecutive LED boards adjusted to the same UV output as one another. In an exemplary testing method, the LED controllers may be set so that a first plate is exposed at an UV intensity of, for example, 311, 200 and 150 mW/cm² (as shown in the “Plate 1 LED power” row of FIG. 5), and a second plate is exposed to intensities of, for example, 100, 50 and 25 mW/cm² (as shown in the “Plate 2 LED power” row), respectively. Although shown with three such sections, it should be understood that the number of sections is preferably variable, as are the number of LEDs in each section, and the relative positioning of the respective sections. Some systems may have controllability of individual LED boards (or groups of boards), whereas others may have controllability of individual LEDs or groups of LEDs within a board.

FIG. 7 shows an example of the resulting areas 206 (1A to 3C) of different exposure parameters in an embodiment of the system in method in which the division of the linear UV head into different sections is combined with stepwise changes in the parameters while the UV head is travelling. Depending on the optical setup of the radiation of the light source sections overlaps for a certain distance.

The UV Irradiance is continuously changing in the overlapping zones, so these zones are not appropriate for the evaluation samples. In FIG. 8, the grey areas 201-204 indicate the zones on the plate not used for sample evaluation, for this reason. Depending on the linear length of the light source and the electronic circuitry for controlling the LEDs, the UV light source may be divided into more or less than three sections. The size of the size of the sections can be altered according to the needs of the application. Likewise, the number of stepwise changes in the direction of relative motion may be fewer or more than three, depending on overall system parameters.

### Various Sample Sizes

In another embodiment, a UV exposure unit with multiple sections can be used for exposing photopolymer plate patches of different sizes and types of photopolymer during one exposure procedure. Given that the pixel time for all polymer plates is identical, the intensity and number of cycles can be altered according to the requirements of each individual plate.

This option may be particularly useful for plate makers in the corrugated business. Corrugated printing plates (e.g. for printing folding cartons) often have only small areas of printed information while most of the area on the printing cylinder does not actually print content. In order to avoid a lot of polymer waste by removing all the non-printing polymer from a full plate, often only small patches of polymer plate are mounted on a plastic carrier sheet, as is described in more detail in U.S Pat. No. 6,954,291, titled “Method, apparatus, and computer program for reducing plate material waste in flexography plate making,” incorporated herein by reference. Often the patches of identical polymer plate for one print job need only a fraction of space on the support surface of the UV exposure unit.

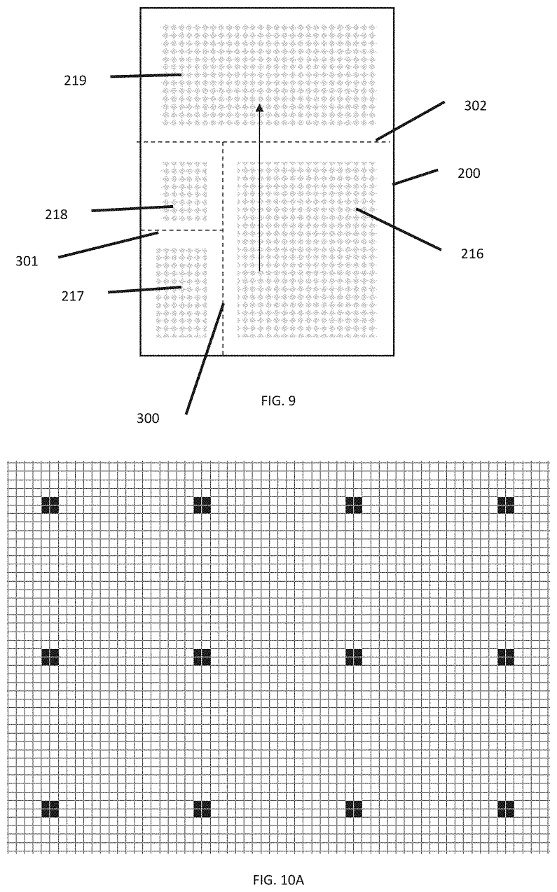

FIG. 9 shows an example of different plate patches on a support surface of an UV exposure unit. Exposure cycles are executed in the direction of arrow A. Whenever the UV head crosses one of the dashed lines parallel to the UV head, the LED sections that cross the line alter their UV output according to the requirements of the next plate patch. The number of exposure steps may be adjusted by deactivating the LED segments for a plate patch having already received a desired number of cycles while activating the LED segments for other patches still in need of more cycles to reach their respective desired number.

If, for example, plate patch 216 in FIG. 9 needs 10 cycles @ 200 mW/cm², patch 217 and 218 need 8 cycles @ 100 mW/cm² and patch 219 needs 6 cycles @ 150 mW/cm², the LED sections alter their UV output according to the areas indicated by the hatched lines. The LED sections are turned off for all remaining exposure cycles when they cross line 302 for the seventh time. After 8 cycles, the LED sections that cover patch 217 and 218 are turned off for cycle 9 and 10 such that only patch 216 gets 10 complete exposure cycles.

A laser scanner or any other kind of imaging projector (e.g. a video projector) may be used to indicate the position of the plate patches on the support surface for the operator that places the patches.

Changing the number of exposure steps received by a sample of printing plate material is not limited to exposures of discrete patches, and may also be applied to portions of a single plate, for example, in the same way that intensity is varied stepwise, a null intensity may be used over certain portions of a single plate to create areas having received more exposure steps than others, with expected “gray areas” in the transitions between areas that are not used for evaluation.

It should be understood that although described herein with respect to UV radiation, the invention is not limited to systems employing radiation in any particular band of radiation, and that the invention may be applied to any system comprising a photopolymer activated by actinic radiation at any wavelength or band of wavelengths. Likewise, the term “light” as used herein in the phrase “light emitting diode” refers to electromagnetic radiation of any wavelength, whether visible to humans or not. The term LED as used herein are not limited to any particular design or materials of construction, and embodies any type of solid-state radiation emission source.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A system for exposing a front, printing side of photopolymer printing plate material located within a target area defined by a first dimension and second dimension, the system comprising:
a light source comprising a plurality of light emitting diodes (LEDs) arranged in an array coextensive with the first dimension;
means for causing relative movement between the light source and the target area along the second dimension;
a control system configurable to cause the light source to emit different light intensities over corresponding portions of the target area in at least one of the first dimension or the second dimension such that the corresponding portions of the target area receive correspondingly different amounts of radiation.

2. The system of claim 1, wherein the array comprising the plurality of LEDs has at least two sections, each section comprising a subset of the plurality of LEDs, and the control system is configurable to cause the at least two sections of the light source to emit different light intensities simultaneously.

3. The system of claim 1, wherein the control system is configurable to cause the light source to emit different a first light intensity over a first portion of the second dimension and a second light intensity over a second portion of the second dimension.

4. The system of claim 3, wherein the control system is configured to cause the change between the first light intensity and the second light intensity to be a stepwise change.

5. The system of claim 1, wherein the control system is configured to cause multiple exposure steps and to cause no light to be emitted by at least a portion of the light source over at least a portion of at least one exposure step.

6. The system of claim 5, wherein the photopolymer printing plate material located within the target area comprises a plurality of patches of plate material, including at least two patches having different plate characteristics.

7. The system of claim 6, wherein the different plate characteristics comprise different types of photopolymer material.

8. The system of claim 6, wherein the different plate characteristics comprise different thicknesses of a same photopolymer material.

9. The system of claim 1, wherein the light source is stationary and the target area comprises a cylinder having a width in the first dimension and a circumferential area in the second dimension, the cylinder configured to rotate beneath the light source to cause the relative movement.

10. The system of claim 1, wherein the target area is stationary and the light source comprises a linear source having a linear dimension coextensive with the first dimension, a width less than the second dimension, and the linear source is mounted to a carriage configured to move in the second dimension to cause the relative movement.

11. The system of claim 1, wherein the plurality of LEDs comprise a plurality of stationary light sources arrayed across an entirety of the first dimension and the second dimension of a stationary target area, and the means for causing relative movement between the light source and the target area comprises a configuration of the controller adapted to activate and deactivate different portions of the array such that activated portions move across the array over time.

12. A method for exposing a front, printing side of photopolymer printing plate material located within a target area defined by a first dimension and second dimension, the method comprising:
providing a light source comprising a plurality of LEDs arranged in an array coextensive with the first dimension;
causing relative movement between the light source and the target area along the second dimension;
causing the light source to emit different light intensities over corresponding portions of the target area in at least one of the first dimension or the second dimension such that the corresponding portions of the target area receive correspondingly different amounts of radiation.

13. The method of claim 12, wherein the array comprising the plurality of LEDs has at least two sections, each section comprising a subset of the plurality of LEDs, and the method comprises causing the at least two sections of the light source to emit different light intensities simultaneously.

14. The method of claim 12, comprising causing the light source to emit different a first light intensity over a first portion of the relative movement and a second light intensity over a second portion of the relative movement.

15. The method of claim 14, comprising causing the change between the first light intensity and the second light intensity to be a stepwise change.

16. The method of claim 12, comprising performing multiple passes of relative movement along the second dimension, wherein no light is emitted by at least a portion of the light source over at least a portion of at least one pass.

17. The method of claim 16, comprising arranging the photopolymer printing plate material within the target area in a plurality of patches of plate material, including at least two patches having different plate characteristics.

18. The method of claim 17, wherein the different plate characteristics comprise different types of photopolymer material.

19. The method of claim 17, wherein the different plate characteristics comprise different thicknesses of a same photopolymer material.

20. A method for determining exposure parameters for curing a selected photopolymer plate having a predetermined photopolymer type and a predetermined plate thickness over multiple exposure steps, the method comprising the steps of:
(a) disposing a sample of photopolymer material in a target area, the sample having the predetermined photopolymer type and the predetermined plate thickness, the target area having a first dimension and second dimension;
(b) providing a first exposure unit comprising a light source comprising a plurality of LEDs arranged in an array coextensive with the first dimension;
(c) causing relative movement between the light source and the target area along the second dimension;
(d) causing different units of the sample to receive different amounts of total energy exposure, different amounts of exposure energy per exposure step, or a combination thereof;
(e) visually evaluating each sample unit against a reference plate having the predetermined photopolymer type and the predetermined plate thickness to identify a sample unit embodying a minimum acceptable total exposure energy and a maximum acceptable exposure energy per exposure step.

21. The method of claim 20, further comprising creating the reference plate by:
selecting an unexposed reference plate having the predetermined photopolymer type and the predetermined plate thickness;
producing an exposed reference plate from the unexposed reference plate using a second exposure unit different from the first exposure unit;
certifying the exposed reference plate as having acceptable quality with respect to a plurality of evaluation parameters.

22. The method of claim 20, comprising providing one or more sample candidates having the predetermined photopolymer type and the predetermined plate thickness, exposing each of the sample candidates or one or more portions thereof to different levels of total back-side energy, and identifying the total back-side exposure energy corresponding to a desired floor depth.

23. The method of claim 20, wherein the plurality of criteria for visually assessing the sample against the reference plate for determining the minimum total exposure energy comprise criteria for determining a minimum stable dot size.

24. The method of claim 23, wherein the criteria for determining a minimum stable dot size are selected from the group consisting of:
(i) first stable dot in a highlight screen field;
(ii) dot size of the first stable dot in the highlight screen field;
(iii) first stable Dotfail test, middle row;
(iv) first stable Dotfail test, bottom row;
(v) first stable isolated dot; and
(vi) any combination of (i)-(v).

25. The method of claim 20, wherein the plurality of criteria for visually assessing the sample against the reference plate for determining the maximum acceptable exposure energy per exposure step are selected from the group consisting of:
(vii) line broadening of horizontal lines;
(viii) line broadening of vertical lines;
(ix) dot cupping in a selected percentage screen;
(x) any combination of (vi)-(ix).

26. The method of claim 25, wherein the selected percentage screen comprises a 50% screen.

27. The method of claim 20, further comprising:
exposing a first sample unit using exposure parameters including a value below the maximum acceptable exposure energy per exposure step and a first number of exposure steps embodying a minimum number of steps at the maximum acceptable exposure energy needed to reach the minimum acceptable total exposure energy;
exposing one or more additional sample units using more than the minimum number of step;
forming one or more printed sheets using each of the first sample unit and the one or more additional sample units; and
visually analysing the printed sheets and identifying exposure parameters corresponding to a desired printed result as an optimum set of exposure parameters for the selected photopolymer plate.

28. The method of claim 20, wherein the step of causing different sample units to receive different amounts of total energy exposure, different amounts of exposure energy per exposure step, or a combination thereof, comprises exposing an entirety of a first test plate area to a first amount of total energy exposure and a first amount of exposure energy per exposure step, and exposing an entirety of a second test plate area to at least one of: a second amount of total energy exposure different than the first amount of total energy exposure, or a second amount of exposure energy per exposure step different than the first amount of exposure energy per exposure step.

29. The method of claim 20, wherein the step of causing different sample units to receive different amounts of total energy exposure, different amounts of exposure energy per exposure step, or a combination thereof, comprises exposing a first sub-area of a first test plate to a first amount of total energy exposure and a first amount of exposure energy per exposure step, and exposing a second sub-area of the first test plate area to at least one of: a second amount of total energy exposure different than the first amount of total energy exposure, or a second amount of exposure energy per exposure step different than the first amount of exposure energy per exposure step.

30. The method of claim 29, wherein the step of causing different sample units to receive different amounts of total energy exposure, different amounts of exposure energy per exposure step, or a combination thereof, comprises causing the light source to emit different light intensities over corresponding portions of the first test plate in at least one of the first dimension or the second dimension.

31. The method of claim 20, wherein the step of causing different units of test plate material to receive different amounts of total energy exposure, different amounts of exposure energy per exposure step, or a combination thereof, comprises causing a portion of the light source to emit no light at least over a portion of at least one exposure step.

32. The method of claim 20, wherein the sample of photopolymer material in a target area comprises a plurality of patches of plate material, including at least one patch with a first predetermined photopolymer type and a first predetermined plate thickness, and at least one other patch having at least one of a second photopolymer type different from the first predetermined photopolymer type or a second plate thickness different from the first predetermined plate thickness.

33. A light source comprising a plurality of light emitting diodes (LEDs) arranged in an array coextensive with a first dimension and a controller configured to control light intensity of independently controllable subsets of the plurality of LEDs, the light source configurable to emit different light intensities simultaneously from at least a first section comprising a first subset of the plurality of LEDs positioned in a first portion of the first dimension, and at least a second section comprising a second subset of the plurality of LEDs positioned in a second portion of the first dimension.

34. A method for exposing photopolymer printing plate material located within a target area defined by a first dimension and second dimension, the method comprising:
providing the light source of claim 33;
causing relative movement between the light source and the target area along the second dimension;
causing the first and second sections of the light source to emit different light intensities over corresponding portions of the target area in the first dimension such that the corresponding portions of the target area receive correspondingly different amounts of radiation.
